(19) United States
(12) Patent Application Publication
(10) Pub. No.: US 2010/0133637 A1
(43) Pub. Date: Jun. 3, 2010

(54) AVALANCHE PHOTODIODE

(75) Inventors: EIJI YAGYU, TOKYO (JP); EITARO ISHIMURA, TOKYO (JP); MASAHARU NAKAJI, TOKYO (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, CHIYODA-KU (JP)

(21) Appl. No.: 12/615,371

(22) Filed: Nov. 10, 2009

(30) Foreign Application Priority Data
Dec. 2, 2008 (JP) 2008-307153

(51) Int. Cl. H01L 31/107

(52) U.S. Cl. 257/438; 257/E31.063

(57) ABSTRACT

An avalanche photodiode comprises: a substrate; a semiconductor layer of a first conductivity type on the substrate; and an avalanche multiplication layer, a light absorption layer, and a window layer which are sequentially formed on the semiconductor layer, wherein apart of the window layer is a region of a second conductivity type, and the light absorption layer includes a first light absorption layer, and a second light absorption layer which has higher electric conductivity than electric conductivity of the first light absorption layer.

### BACKGROUND OF THE INVENTION

1. Field of the Invention

The present invention relates to an avalanche photodiode used in such as optical fiber communication, wherein a light receiving sensitivity is raised by utilizing a phenomenon called an avalanche multiplication.

2. Background Art

An avalanche photodiode includes a light absorption region and an avalanche multiplication region. When light inputs into the avalanche photodiode to which a reverse bias voltage is applied, the light is absorbed in the light absorption region and electron-hole pairs are generated therein. The photo carriers generated in the light absorption region are multiplied like an avalanche by ionization collision in the avalanche multiplication region to which a high voltage is applied. Not only high sensitivity and high-speed response but also high reliability, low power consumption, and high efficiency are required in an avalanche photodiode which receives near-infrared light and is used in the optical fiber communication.

In such an avalanche photodiode which receives near-infrared light, it was known that an electric field is applied to only an inside region of the photodiode for a long-life operation and speeding up by reduction of the capacitance (refer to, for example, pages 5 to 6 of Japanese Patent Application Laid-Open No. 2005-539368). In such an avalanche photodiode, a light absorption layer is ordinarily undoped or slightly-doped (about 1.0×10¹⁶ cm⁻³).

A light absorption layer of an avalanche photodiode including a depleted layer that is depleted during an operation and a depletion terminal layer having a higher carrier concentration than the depleted layer in order to satisfy both of the high quantum efficiency and the high-speed response was known (refer to, for example, pages 4 to 5 of Japanese Patent Application Laid-Open No. 2003-46114).

### SUMMARY OF THE INVENTION

However, in the conventional avalanche photodiode including a light absorption layer constituted of two layers, an un-depleted region to which an electric field is not applied is generated since the region has a low-resistance. Therefore, electrons and holes do not drift at high speeds, and thus being increasingly disappeared by recombination. As a result, sensitivity and responsiveness for light are reduced.

If the light absorption layer is undoped in the conventional avalanche photodiode having the light absorption layer constituted of one layer, a uniform electric field is applied to the light absorption layer. Therefore, a bias voltage during an operation is increased, and thus the power consumption is increased. On the other hand, if the light absorption layer is slightly doped, the carrier concentration can not be increased, because a tunnel dark current and the reduction of the responsiveness for light need to be prevented. Therefore, the carrier concentration needs to,be precisely controlled at 10¹⁵ cm⁻³ level during the crystal growth. However, if the metalorganic chemical vapor deposition (MOCVD) or the molecular beam epitaxy (MBE) is used for the crystal growth, the light absorption layer has n-type or p-type conductivity at 10¹⁵ cm⁻³ level even if impurities are not intentionally doped therein. Therefore, it was very difficult to precisely control the carrier concentration of the light absorption layer.

In view of the above-described problem, an object of the present invention is to provide an avalanche photodiode that can be easily fabricated and has high light receiving sensitivity with low power consumption.

According to one aspect of the present invention, an avalanche photodiode comprises: a substrate; a semiconductor layer of a first conductivity type on the substrate; and an avalanche multiplication layer, a light absorption layer, and a window layer which are sequentially formed on the semiconductor layer, wherein a part of the window layer is a region of a second conductivity type, and the light absorption layer includes a first light absorption layer, and a second light absorption layer which has higher electric conductivity than electric conductivity of the first light absorption layer.

According to the present invention, an avalanche photodiode that can be easily fabricated and has high light receiving sensitivity with low power consumption can be provided.

Other and further objects, features and advantages of the invention will appear more fully from the following description.

### BRIEF DESCRIPTION OF THE DRAWINGS

FIG. 1 is a cross-sectional view showing an avalanche photodiode according to a first embodiment.

FIG. 2 is a top view showing an avalanche photodiode according to a first embodiment.

FIG. 3 is a view showing an electric field intensity distribution in the depth direction of the avalanche photodiode according to a first embodiment.

FIGS. 4-10 are cross-sectional views showing an avalanche photodiode according to a first embodiment.

FIG. 11 is a cross-sectional view showing an avalanche photodiode according to a second embodiment.

### DETAILED DESCRIPTION OF THE PREFERRED EMBODIMENTS

Now, embodiments of the present invention will be described with reference to the drawings. Same reference numerals denote same components throughout the drawings, and redundant descriptions will be omitted.

### First Embodiment

FIG. 1 is a cross-sectional view showing an avalanche photodiode according to a first embodiment. The following description of the present embodiment assumes that a first conductivity type is an n-type and a second conductivity type is a p-type.

In FIG. 1, a buffer layer 20 made of n-type InP is provided on a first major surface of a substrate 10 made of InP which has a low resistance and n-type conductivity. The buffer layer 20 has a carrier concentration of 1 to 5×10¹⁸ cm⁻³ and a thickness of 0.1 to 1 μm. An avalanche multiplication layer 30 made of undoped AlInAs is provided on the buffer layer 20. The avalanche multiplication layer 30 has a carrier concentration of 0.1 to 3×10¹⁵ cm⁻³ and a thickness of 0.1 to 0.5 μm. An electric field control layer 40 made of p-type InP is provided on the avalanche multiplication layer 30. The electric field control layer 40 has a carrier concentration of 0.1 to 1×10¹⁸ cm⁻³ and a thickness of 0.01 to 0.1 μm. An undoped light absorption layer 51 made of GaInAs and an n-type light absorption layer 52 made of GaInAs are sequentially formed on the electric field control layer 40. The undoped light absorption layer 51 has a thickness of 0.5 to 2 μm. The n-type light absorption layer 52 has a carrier concentration of 0.3 to 3×10¹⁶ cm⁻³ and a thickness of 0.2 to 2 μm. An n-type window layer 61 made of AlInAs and an undoped window layer 62 made of AlInAs are sequentially formed on the n-type light absorption layer 52. The n-type window layer 61 has a carrier concentration of 0.3 to 3×10¹⁶ cm⁻³ and a thickness of 0.5 to 2 μm. The undoped window layer 62 has a thickness of 0.5 to 2 μm.

Here, a set of the undoped light absorption layer 51 (a first light absorption layer) and the n-type light absorption layer 52 (a second light absorption layer) is called a light absorption layer 50. A set of the n-type window layer 61 and the undoped window layer 62 is called a window layer 60. Of course, the electric conductivity of the undoped light absorption layer 51 is different from the electric conductivity of the n-type light absorption layer 52. The electric conductivity of the n-type light absorption layer 52 is higher than the electric conductivity of the undoped light absorption layer 51. An electric conductivity of the n-type window layer 61 is higher than the conductivity of the undoped window layer 62.

The composition of the layers made of GaInAs or AlInAs are adjusted so that the layers are almost lattice-matched with the layers made of InP. The band gap of the GaInAs material is smaller than the band gap of the InP material. The band gap of the InP material is smaller than the band gap of the AlInAs material.

When viewed from top surfaces of the n-type window layer 61 and the undoped window layer 62, a p-type region 80 is formed in a region having a diameter of 20 to 100 μm around the center portion of the avalanche photodiode. When viewed from a top surface of the p-type region 80, a contact region 70 made of p-type GaInAs is formed into a ring shape having a width of 5 to 10 μm on the circumference surface of the p-type region 80.

A p-electrode 100 composed of Ti/Au is formed on the top surface of the p-type contact region 70. A protective film 90 made of SiNx is formed on a region of the top surface of the undoped window layer 62 where the contact region 70 is not formed. An n-electrode 110 composed of AuGe/Ni/Au is formed on the entire surface opposite from the first major surface of the substrate 10.

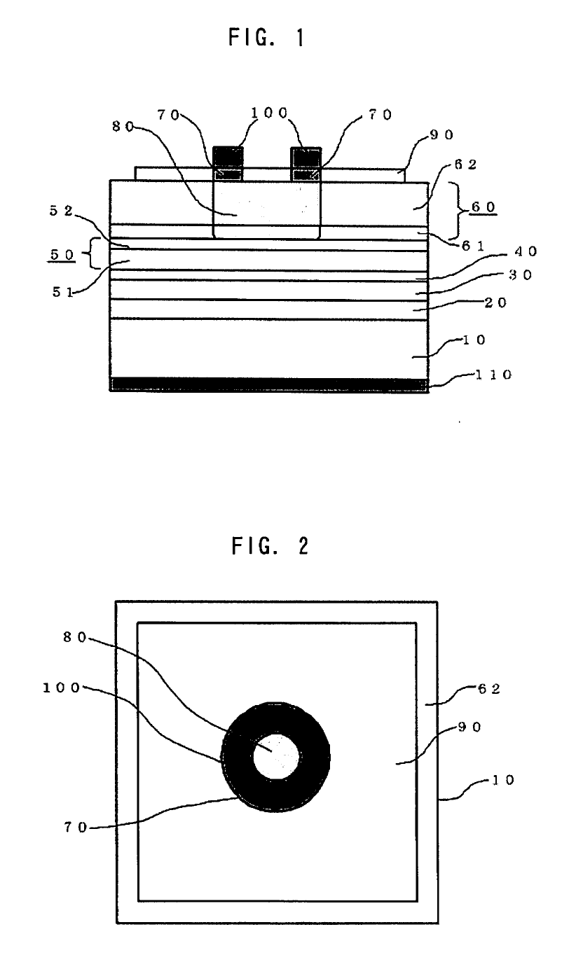

FIG. 2 is a top view showing an avalanche photodiode according to a first embodiment. As shown in FIG. 2, the substrate 10 and the undoped window layer 62 formed on the substrate 10 have rectangular shapes of about 300 μm square. The p-type region 80 is formed in the undoped window layer 62. The p-type contact region 70 and the p-electrode 100 are formed on the circumference of the p-type region 80.

Although not shown in FIGS. 1 and 2, an extractor electrode connected to the p-electrode 100 is generally provided on the top surface of the avalanche photodiode.

Next, the method for manufacturing the avalanche photodiode of the present embodiment will be described below. The avalanche photodiode showed in FIGS. 1 and 2 is manufactured as described below.

First, the buffer layer 20 made of n-type InP, the avalanche multiplication layer 30 made of undoped AlInAs, the electric field control layer 40 made of p-type InP, the undoped light absorption layer 51 made of GaInAs, the n-type light absorption layer 52 made of GaInAs, the n-type window layer 61 made of AlInP, the undoped window layer 62 made of AlInAs, and a contact layer made of undoped GaInAs are sequentially epitaxially grown on the substrate 10 made of n-type InP by such as the metalorganic chemical vapor deposition or the molecular beam epitaxy.

Next, a diffusion mask SiNx film is formed on the above-described epitaxially grown layers by the chemical vapor deposition. The region of the diffusion mask SiNx film except a predetermined light-receiving region having a diameter of 20 to 100 μm is removed. Next, Zn is selectively heat-diffused from the region where the diffusion mask is removed, into the undoped type contact layer, the undoped window layer 62, and the n-type window layer 61. After the heat diffusion of Zn, the undoped type contact layer is converted to the p-type contact layer, and a Zn-diffused region in the undoped window layer 62 and the n-type window layer 61 is converted to the p-type region 80. After the remaining diffusion mask SiNx film is removed, the p-type contact layer is formed into a ring shape having a width of 5 to 10 μm by removing an unwanted portion thereof so as to form the p-type contact layer 70. Next, a SiNx surface protective layer is formed on the contact region 70, the p-type region 80, and the undoped window layer 62. A portion of the SiNx surface protective layer provided on the top surface of the contact region 70 and other unwanted portions thereof are removed so as to form a protective film 90 made of SiNx. Next, Ti/Au films are deposited on the top surface of the p-type contact region 70 so as to form the p-electrode 100.

Furthermore, the substrate 10 is thinned by etching and polishing the back surface thereof. AuGe/Ni/Au films are deposited on the entire back surface of the substrate 10 so as to form the n-electrode 110. After the p-electrode 100 and the n-electrode 110 are ohmic-joined by a sintering treatment, the substrate 10 is separated by cleavage. As a result, the avalanche photodiode of about 300 μm square showed in FIGS. 1 and 2 can be obtained.

The protective film 90 made of SiNx also functions as an anti-reflection film. The thickness of the protective film 90 is selected so that the protective film 90 functions as the anti-reflection film.

Next, the operation of the avalanche photodiode according to the present embodiment will be described below.

Light to be detected is input from the p-electrode 100 side into the p-type region 80, while a reverse bias voltage is applied to the avalanche photodiode from outside so that a positive potential is applied to the n-electrode 110 and a negative potential is applied to the p-electrode 100. If near-infrared light, which has a wavelength range of 1.3 μm band or 1.5 μm band used in optical communications, is input, this input light is absorbed in the depleted the depleted undoped window layer 62 or n-type window layer 61, and thereby electron-hole pairs are generated. The electrons are moved to the n-electrode 110 side and the holes are moved to the p-electrode 100 side. Since the reverse bias voltage is made to be sufficiently-high, the electrons are ionized in the avalanche multiplication layer 30 and new electron-hole pairs are generated there. These generated electrons and holes are also ionized, and thereby an avalanche multiplication wherein electrons and holes are multiplied like an avalanche is caused.

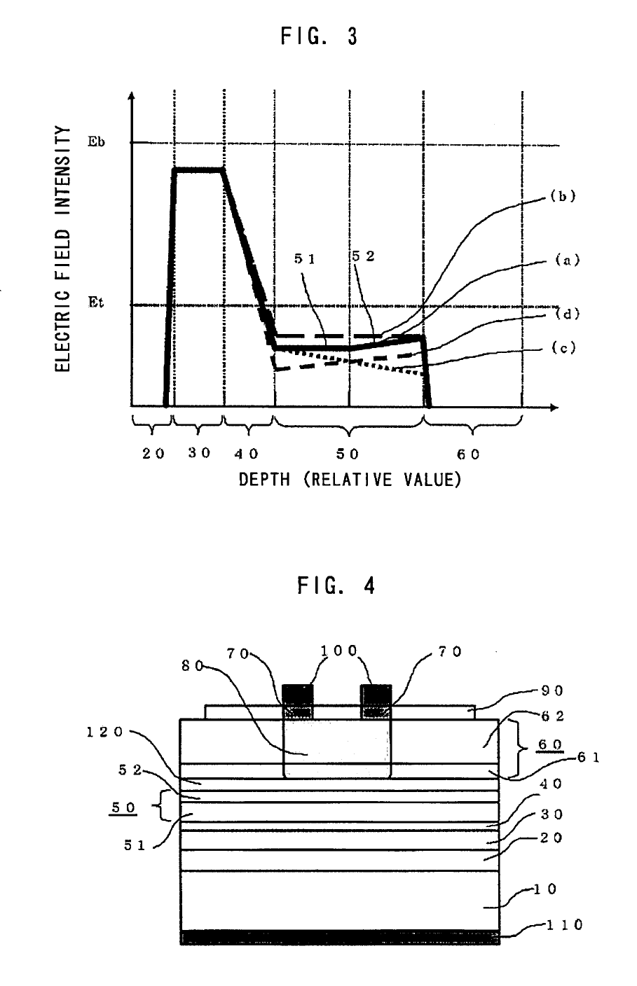

FIG. 3 is a view showing an electric field intensity distribution in the depth direction of the avalanche photodiode according to the present embodiment in comparison with electric field intensity distributions in the depth direction of an avalanche photodiode having a light absorption layer being an undoped single layer, an avalanche photodiode having a light absorption layer being a p-type single layer, and an avalanche photodiode having a light absorption layer being an n-type single layer. (a) in FIG. 3 is the electric field intensity distribution of the avalanche photodiode according to the present embodiment. (b) in FIG. 3 is the electric field intensity distribution of the avalanche photodiode having the light absorption layer 50 being an undoped single layer. (c) in FIG. 3 is the electric field intensity distribution of the avalanche photodiode having the light absorption layer 50 being a p-type single layer. (d) in FIG. 3 is the electric field intensity distribution of the avalanche photodiode having the light absorption layer 50 being an n-type single layer.

In FIG. 3, Eb is an electric field intensity wherein the endless chain avalanche multiplication is caused in the avalanche multiplication layer and thereby the avalanche break down happens. Et is an upper limit electric field intensity to prevent the tunnel current through the light absorption layer. Eb is generally 60 MV/m or larger. Et is generally 20 MV/m or smaller, preferably 15 MV/m or smaller.

In FIG. 3(a), the high electric field is applied to the avalanche multiplication layer 30 so as to cause the ionization collision and obtain the avalanche multiplication. On the other hand, the electric field having a certain level or larger is applied to the the light absorption layer 50 so that the carriers generated by the light absorption can drift at high speeds. Its level is controlled by the electric field control layer 40 so as to be equal to or smaller than the electric field Et which causes the tunnel dark current.

In the avalanche photodiode according to the present embodiment, the light absorption layer 50 is a two-layers-structure having the undoped light absorption layer 51 and the n-type light absorption layer 52. Therefore, as shown in FIG. 3(a), the variation of the electric field intensity in the depth direction is negligibly-small and constant in the undoped light absorption layer 51, and the electric field intensity varies in the depth direction in the n-type light absorption layer 52.

On the other hand, in FIG. 3(b), the almost constant electric field is applied to the entire light absorption layer 50. The possibly high electric field but smaller than Et is applied to the light absorption layer 50, so that the optical response can be obtained in even the low bias electric field intensity and the carriers are not piled up at the interface between the light absorption layer 50 and the window layer 60 to lower the response speed.

The bias voltage applied to the avalanche photodiode is obtained as an integral of the electric field, that is to say, the area of the lower part under each line shown in FIG. 3. The area of the lower part of FIG. 3(a) is smaller than that of FIG. 3(b). Therefore, the avalanche photodiode according to the present embodiment can operate in lower bias voltage than that of the avalanche photodiode having the light absorption layer being the undoped single layer, that is to say, in low power consumption.

When the light absorption layer 50 is a single conductivity type layer such as a p-type single layer or an n-type single layer, the high light sensitivity and the high optical response can be obtained in even the low bias electric field and the avalanche photodiode can operate in small bias voltage as shown in FIGS. 3(c) and (d). However, some limitations are occurred by the other viewpoint.

If the voltage depleting the entire light absorption layer 50 is not applied to the avalanche photodiode during the operation, the efficiency reduces as disclosed in Japanese Patent Application Laid-Open No. 2003-46114. The electric field intensity variation dE depleting the entire light absorption layer 50 is represented by the following equation:

dE=(q×t/ε)×N (1)

where q is the elementary charge, t is the thickness of the light absorption layer (cm), ε is the dielectric constant of the light absorption layer (F/m), and N is the carrier concentration of the light absorption layer (cm⁻³). As represented by the equation (1), when the film thickness t is smaller, same electric field intensity variation can be obtained and the carrier concentration can become larger.

As represented by the equation (1), when the density of the impurities doped in the light absorption layer 50 slightly increases and thereby the carrier concentration increases, the carriers in the light absorption layer 50 similarly increases and thereby the electric field intensity depleting the entire light absorption layer 50 also increases. Since this electric field intensity needs to be controlled to be smaller than Et, the advanced control of the density of the impurities doped in the light absorption layer 50 is needed. However, as described above, it is difficult to form, by CVD etc, the n-type or p type film having the carrier concentration preciously controlled to 10¹⁵ cm⁻³ level. Therefore, large electric field is applied in light of the variation of the carrier concentration. As a result, the power consumption becomes large.

As described above, in the avalanche photodiode according to the present embodiment, the thicknesses and the impurity concentrations of the undoped light absorption layer 51 and the n-type light absorption layer 52 are selected so that the light absorption layer 50 is fully depleted in a depth direction. In particular, the impurity concentration of the n-type light absorption layer 52 is 0.3×10¹⁵ cm⁻³ or larger and 3×10¹⁵ cm⁻³ or smaller. Therefore, even if the bias voltage is low during the operation, certain light sensitivity and high-speed response can be obtained. As a result, it is possible to obtain an avalanche photodiode which has lower power consumption than that of the avalanche photodiode shown in FIG. 3(b) having the undoped light absorption layer constituted of one layer and wherein tunnel current is ungenerable in low power consumption as compared to the avalanche photodiode shown in FIG. 3(c) or (d) having the entire light absorption layer 50 being conductive.

In the avalanche photodiode according to the present embodiment, the pile-up of the holes can be prevented. Therefore, high-speed response can be realized.

In the avalanche photodiode according to the present embodiment including the light absorption layer 50 having a narrow band gap and the window layer 60 having a wide band gap, band discontinuity is generated mainly in the valence band of the hetero interface between the light absorption layer 50 and the window layer 60. The band discontinuity in the valence band piles up the holes. The pile-up of holes having large effective masses particularly reduces response speed. This phenomenon is significant, when the electron density in the window layer 60 is low.

In this manner, in the avalanche photodiode according to the present embodiment, high electric field is applied to the p-type region 80 side of the light absorption layer 50 from the time of low bias voltage. Therefore, this electric field prevents the generation of pile-up of holes, and thereby high-speed response can be realized.

Furthermore, in the avalanche photodiode according to the present embodiment, the phenomenon called the edge break down can be prevented. In the phenomenon, the avalanche multiplication is generated in only a part of the avalanche multiplication layer 30 just below the peripheral part of the p-type region 80. The reason will be described below.

The interface of the p-type region 80, which is generated by Zn diffusion from the surface, has curvature at the cross-sectional corner part, as shown in FIG. 1. Therefore, at the cross-sectional corner part of the p-type region 80, the density of Zn generating acceptors becomes lower, that is to say, the density of electrons being n-type carriers becomes higher.

The electric field intensity Ec at the cross-sectional corner part is provided by Poisson equation and is represented by the following equation:

Ec=1/(κ ε0r)∫^{r} r ρ drC/r (2)

where r is the curvature radius of the cross-sectional corner part, ρ is the charge density distribution in the radial direction, ε 0 is the vacuum dielectric constant, κ is the relative permittivity, and C is a constant value. As represented by the equation (2), the electric field intensity Ec at the cross-sectional corner part becomes higher, when the charge density distribution (in this case, n-type carrier concentration) is higher. If the electric field intensity Ec at the cross-sectional corner part of the p-type region 80 is large, the electric field intensity in the avalanche multiplication layer 30 just below them relatively becomes smaller. Therefore, the edge break down in the avalanche multiplication layer 30 can be prevented.

Impurities are not intentionally doped in the undoped light absorption layer 51 and the undoped window layer 62. However, there is a possibility that they have slight conductivity due to such as impurities contained in raw materials. Therefore, the n-type light absorption layer 52 and the n-type window layer 61 preferably have higher impurity concentrations than those of the above described layers which are not intentionally doped. If the n-type light absorption layer 52 and the n-type window layer 61 are n-type, the electric field intensity can be increased at the interface in the moving direction of the holes. Therefore, the pile-up of the holes can be prevented. Furthermore, the edge break down in the peripheral part can be prevented.

In the present embodiment, both of the light absorption layer 50 and the window layer 60 are constituted of a plurality of layers. In addition to this, the window layer 60 can be constituted of one layer. The light absorption layer 50 can be a layer whose carrier concentration (impurity concentration) changes continuously in a part of the layer or the entire layer, instead of the structure constituted of a plurality of layers.

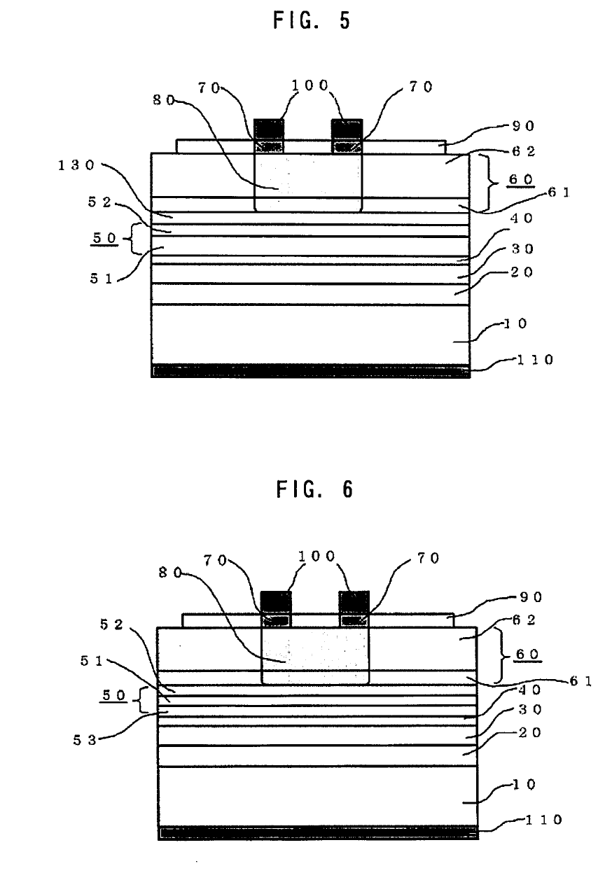

In the avalanche photodiode according to the present embodiment, the light absorption layer 50 is directly connected to the window layer 60. In addition to this, as shown in FIG. 4, an anti-pile-up layer 120, which includes a valence band having an energy level between that of the light absorption layer 50 and that of the window layer 60, can be provided between the light absorption layer 50 and the window layer 60. As shown in FIG. 5, a diffusion blocking layer 130 can be provided between the light absorption layer 50 and the window layer 60 so as to suppress the diffusion of Zn. The anti-pile-up layer 120 and the diffusion blocking layer 130 are preferably n-type. When they are n-type, the electric field intensity can be increased at the interface in the moving direction of the holes. Therefore, the pile-up of the holes can be prevented. Furthermore, the edge break down in the peripheral part can be prevented.

Furthermore, in the present embodiment, the light absorption layer 50 is a two-layer-structure having an undoped layer and n-type layer in the order from the avalanche multiplication layer 30 side. In addition to this, the light absorption layer 50 can be constituted of two or more layers freely selected from undope, n-type, and p-type layers. For example, the light absorption layer 50 can be constituted of undoped/p-type layers in the order from the avalanche multiplication layer 30 side. The light absorption layer 50 can be constituted of n-type/undoped layers, n-type/n-type layers, n-type/p-type layers, p-type/undoped layers, p-type/n-type layers, or p-type/p-type layers in the order from the avalanche multiplication layer 30 side.

When the light absorption layer 50 has a p-type layer and a n-type layers, the electric field intensity in the light absorption layer 50 reduces toward the window layer 60 side. Therefore, the density range of both p-type and n-type carriers can be wide, and thereby the avalanche photodiode can be easily fabricated. In this case, the n-type carrier concentration can be increased. Therefore, the electric field intensity can be increased and the pile-up can be prevented. Furthermore, the edge break down in the peripheral part can be prevented.

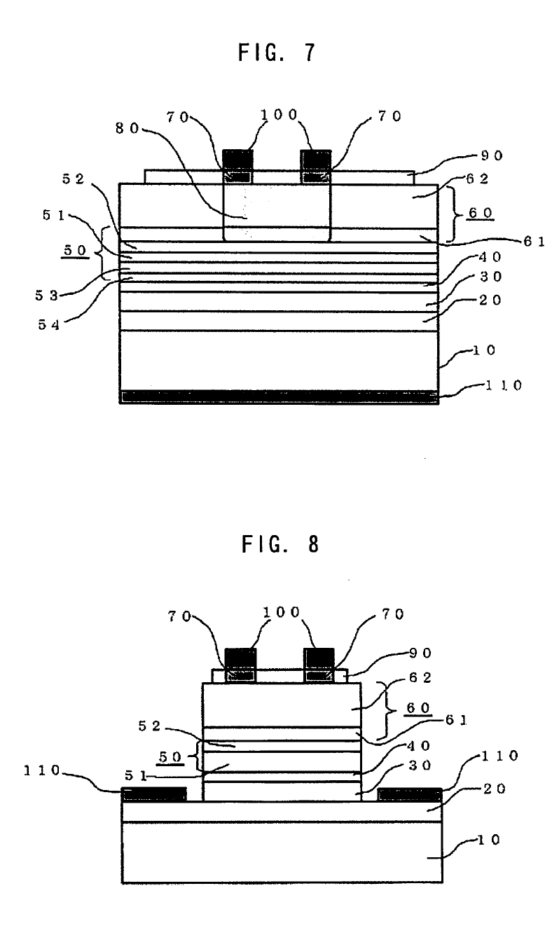

Even if the light absorption layer 50 is constituted of three or more layers, the same advantages as those of the case of two layers can be obtained. The typical examples will be described below. As shown in FIG. 6, the light absorption layer 50 can be a three-layer-structure having the p-type light absorption layer 53, the undoped light absorption layer 51, and the n-type light absorption layer in the order from the avalanche multiplication layer 30. As shown in FIG. 7, the light absorption layer 50 can be a four-layer-structure having the n-type light absorption layer 54, the p-type light absorption layer 53, the undoped light absorption layer 51, and the n-type light absorption layer 52. In these examples, a p-type part (p-type light absorption layer 53) in the light absorption layer 50 reduces the electric field intensity in a part (undoped light absorption layer 51) which connects the p-type part. Therefore, the electric field intensity in the the window layer 60 side of the following n-type light absorption layer 52 can be increased, and thereby the avalanche photodiode having high-speed response and low power consumption can be obtained. The n-type part and the p-type part are selected so that the electric field intensities therein compensate each other and are balanced.

In the avalanche photodiode according to the present embodiment, the n-electrode 110 is provided so as to contact the n-type substrate 10. In addition to this, as shown in FIG. 8, the n-type buffer layer 20 can be exposed and the n-electrode 110 can be provided so as to contact the n-type buffer layer 20. In the structure shown in FIG. 8, the substrate 10 need not have a low resistance, and thereby a semi-insulating substrate can be used instead of the n-type substrate 10 having a low resistance. If the semi-insulating substrate is used, the capacitance of the element can be reduced. Therefore, the avalanche photodiode operating at high speed can be obtained. Since the semi-insulating substrate does not absorb much light, the backside incidence structure wherein the light enters from the substrate side can be adapted.

Further, not only the surface incidence or backside incidence structure but also the side incidence structure can be adapted. For example, when the waveguide structure is adapted, the capacitance of the element can be reduced further. Therefore, the avalanche photodiode operating at higher speed can be obtained.

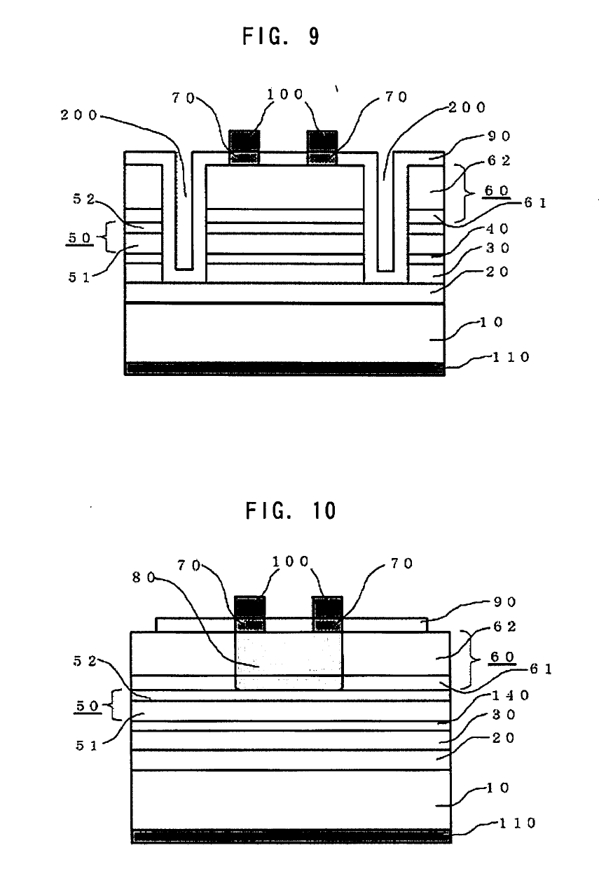

In the avalanche photodiode according to the present embodiment, as shown in FIG. 1, the side surface of the depleted avalanche multiplication layer 30 is exposed. In addition to this, as shown in FIG. 9, the ring-shaped groove 200 can be formed from the top surface side to the layer under the avalanche multiplication layer 30 and the protective film 90 can be provided in the ring-shaped groove 200 so as to protect the side surface of the avalanche multiplication layer 30. The dark current, which is a current when the light does not enter, can be reduced by protecting the side surface of the avalanche multiplication layer 30. In addition, the dark current can be reduced further by slightly etching the side surface of the light absorption layer 50 exposed in the ring-shaped groove 200 before providing the protective film 90.

In the avalanche photodiode according to the present embodiment, the avalanche multiplication layer 30 and the electric field control layer 40 are individually provided. In addition to this, the avalanche multiplication layer 30 can be a p-type layer so as to perform as both of the avalanche multiplication layer 30 and the electric field control layer 40. The avalanche multiplication layer 30 according to the present embodiment is made of AlInAs. In addition to this, the avalanche multiplication layer 30 can be a quaternary mixed crystal layer such as AlGaInAs or GaInAsP, or a super lattice structure having an AlInAs layer and the other composition layer, if the ionization rate of electrons is higher than the ionization rate of holes in the avalanche multiplication layer 30.

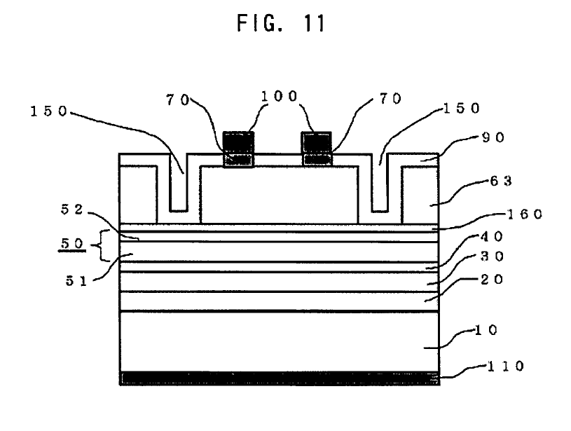

As shown in FIG. 10, the conduction band continuous layer 140 reducing the band discontinuity in the conduction band can be provided instead of the electric field control layer 40 between the avalanche multiplication layer 30 and the light absorption layer 50, so that the electrons can easily move from the light absorption layer 50 to the avalanche multiplication layer 30 and thereby the pill-up of electrons can be prevented. The conduction band continuous layer 140 can be p-type so as to have the function of the electric field control layer 40 as shown in FIG. 1. The conduction band continuous layer 140 can be undoped or n-type so as to apply high electric field to help electrons move and thus realize high-speed response.

Furthermore, in the avalanche photodiode according to the present embodiment, the light absorption layer 50 is constituted of two layers. In addition to this, the light absorption layer 50 can be, instead of the multiple layer structure, a layer whose carrier concentration changes continuously in a part of the layer or the entire layer.

The other acceptor impurity such as Cd can be used instead of Zn so as to form the p-type region 80.

### Second Embodiment

FIG. 11 is a cross-sectional view showing an avalanche photodiode according to a second embodiment. In FIG. 11, the p-type window layer 63 constituted of one layer is provided, instead of the window layer 60 constituted of two layers according to the first embodiment. The etching stopper layer 160 is provided between the p-type window layer 63 and the light absorption layer 50. The ring-shaped groove 150 is provided so that a p-type window layer 63 is formed in an island shape having a diameter of 20 to 100 μm and a desired light receiving size. Other components are similar to those of the first embodiment, thus detailed descriptions will be omitted.

The p-type window layer 63 is made of AlInAs and has a carrier concentration of 0.3 to 3×10¹⁶ cm⁻³ and a thickness of 0.5 to 2.0 μm. The etching stopper layer 160 is made of n-type InP and has a carrier concentration of 0.3 to 3×10¹⁶ cm⁻³ and a thickness of 0.01 to 0.05 μm. The contact region 70 is made of p-type GaInAs and has a carrier concentration of 0.01 to 1×10¹⁵ cm⁻³ and a thickness of 0.1 to 0.5 μm.

Next, the main part of the method for manufacturing the avalanche photodiode of the present embodiment will be described below. First, the buffer layer 20 made of n-type InP, the avalanche multiplication layer 30 made of undoped AlInAs, the electric field control layer 40 made of p-type InP, the undoped light absorption layer 51 made of GaInAs, the n-type light absorption layer 52 made of GaInAs, the etching stopper layer 160 made of InP, the p-type window layer 63 made of AlInAs, and a contact layer made of p-type GaInAs are sequentially epitaxially grown on the substrate 10 made of n-type InP by such as the metalorganic chemical vapor deposition or the molecular beam epitaxy.

The contact layer is formed into a ring shape having a width of 5 to 10 μm by etching so as to form the p-type contact layer 70. Next, the p-type window layer 63 is etched to the etching stopper layer 160 so as to be formed in an island shape having a diameter of 20 to 100 μm and a desired light receiving size. As a result, the ring-shaped groove 150 is provided. Next, the protective film 90 made of SiNx is formed. A portion of the protective film 90 which is provided on the contact region 70 is removed. The first electrode 100 is formed by depositing Ti/Au on the exposed contact region 70.

In the second embodiment, the avalanche photodiode having the same characteristics as those of the avalanche photodiode according to the first embodiment can be obtained without the Zn diffusion process. An avalanche photodiode that can be easily fabricated and has high light receiving sensitivity and high-speed response in low power consumption can be provided, as in the first embodiment.

In the avalanche photodiode according to the present embodiment, as in the first embodiment, the p-type window layer 63 that is a light receiving part can have very small curvature in the peripheral part. Therefore, the p-type window layer 63 has high electron density in the peripheral part. Since the etching stopper layer 160 and the light absorption layer 50 in the peripheral part of the p-type window layer 63 have high electron density, the electric field intensity Ec becomes large. Therefore, the electric field intensity in the avalanche multiplication layer 30 just below them relatively becomes smaller. As a result, the edge break down in the avalanche multiplication layer 30 can be prevented.

In the present embodiment, the groove 150 is formed into a ring shape. In addition to this, the groove 150 can be formed into other shape such as a square shape, a polygonal shape, or an ellipsoidal shape. Furthermore, all periphery portions can be removed.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2008-307153, filed on Dec. 2, 2008 including specification, claims, drawings and summary, on which the Convention priority of the present application is based, are incorporated herein by reference in its entirety.

What is claimed is:

1. An avalanche photodiode comprising:
a substrate;
a semiconductor layer of a first conductivity type on the substrate; and
an avalanche multiplication layer, a light absorption layer, and a window layer which are sequentially formed on the semiconductor layer,
wherein a part of the window layer is a region of a second conductivity type, and
the light absorption layer includes a first light absorption layer, and a second light absorption layer which has higher electric conductivity than electric conductivity of the first light absorption layer.

2. The avalanche photodiode according to claim 1, wherein the second light absorption layer is formed on the window layer side of the first light absorption layer.

3. The avalanche photodiode according to claim 2, wherein the second light absorption layer is a light absorption layer of the first conductivity type, and the first light absorption layer is an undoped light absorption layer.

4. The avalanche photodiode according to claim 1, wherein the light absorption layer includes a light absorption layer of the first conductivity type and a light absorption layer of the second conductivity type.

5. The avalanche photodiode according to claim 1, wherein the light absorption layer includes an undoped light absorption layer and a light absorption layer of the second conductivity type.

6. The avalanche photodiode according to claim 1, further comprising an anti-pile-up layer or a diffusion blocking layer between the light absorption layer and the window layer.

7. An avalanche photodiode comprising:
a substrate;
a semiconductor layer of a first conductivity type on the substrate; and
an avalanche multiplication layer, alight absorption layer, and a window layer of a second conductivity type which are sequentially formed on the semiconductor layer,
wherein the window layer includes a groove which reaches a layer contacting a lower side of the window layer, and
the light absorption layer includes a first light absorption layer, and a second light absorption layer which has higher electric conductivity than electric conductivity of the first light absorption layer.

8. The avalanche photodiode according to claim 7, wherein the second light absorption layer is formed on the window layer side of the first light absorption layer.

9. The avalanche photodiode according to claim 8, wherein the second light absorption layer is a light absorption layer of the first conductivity type, and the first light absorption layer is an undoped light absorption layer.

10. The avalanche photodiode according to claim 1, wherein the light absorption layer is fully depleted in a depth direction of the light absorption layer during an operation.

11. The avalanche photodiode according to claim 7, wherein the light absorption layer is fully depleted in a depth direction of the light absorption layer during an operation.

12. The avalanche photodiode according to claim 3, wherein the light absorption layer of the first conductivity type includes an impurity concentration of 0.3×10¹⁵ cm⁻³ to 3×10¹⁵ cm⁻³.

13. The avalanche photodiode according to claim 9, wherein the light absorption layer of the first conductivity type includes an impurity concentration of 0.3×10¹⁵ cm⁻³ to 3×10¹⁵ cm⁻³.
